(19) United States
(12) Patent Application Publication
(10) Pub. No.: US 2025/0030448 A1
(43) Pub. Date: Jan. 23, 2025

(54) AMPLIFIER MODULE AND WIRELESS COMMUNICATION SYSTEM

(71) Applicant: ALPS ALPINE CO., LTD., Tokyo (JP)

(72) Inventors: Kazuhiro AOYAGI, Shanghai (CN); Takeshi IISAKA, Miyagi-ken (JP); Tsutomu KUNISHIMA, Miyagi-ken (JP)

(21) Appl. No.: 18/664,378

(22) Filed: May 15, 2024

(30) Foreign Application Priority Data
Jul. 18, 2023 (JP) 2023-116781

(51) Int. Cl. H04B 1/401; H03F 3/19

(52) U.S. Cl. CPC H04B 1/401; H03F 3/19; H03F 2200/451

(57) ABSTRACT

An amplifier module is disposed between an antenna for wireless communication and a main body portion of a wireless communication device, and is connected to the antenna via a first wiring member and to the main body portion via a second wiring member. The amplifier module includes an antenna-side terminal connected to the first wiring member, a main body-side terminal connected to the second wiring member, an amplifier disposed between the antenna-side terminal and the main body-side terminal, an impedance detector that detects impedance of the antenna-side terminal, a determiner that determines a connection state of the antenna to the antenna-side terminal based on the impedance detected by the impedance detector, and a controller that causes the amplifier to output a first state signal representing the connection state to the main body-side terminal, when the determiner determines that the connection state is abnormal.

### CLAIM OF PRIORITY

This application claims benefit of Japanese Patent Application No. 2023-116781 filed on Jul. 18, 2023, which is hereby incorporated by reference.

### BACKGROUND OF THE INVENTION

### 1. Field of the Invention

The present invention relates to an amplifier module and a wireless communication system.

### 2. Description of the Related Art

In general, an amplifier module that is disposed between an antenna for wireless communication and a main body portion of a wireless communication device and that is connected to the antenna and the main body portion through wiring members has been used. The amplifier module includes an antenna-side terminal connected to the antenna, a main body-side terminal connected to the main body portion, an amplifier circuit disposed between the antenna-side terminal and the main body-side terminal, an antenna detection circuit that detects electrical characteristics of the antenna-side terminal, and a characteristic variable circuit that changes electrical characteristics of the main body-side terminal based on the electrical characteristics of the antenna-side terminal detected by the antenna detection circuit (refer to, for example, International Publication No. 2020/059172).

General amplifier modules require a characteristic variable circuit that changes electrical characteristics of a main body-side terminal and leave room for further simplification of a configuration.

### SUMMARY OF THE INVENTION

The present invention provides an amplifier module and a wireless communication system with a simple configuration that may notify a main body portion of a connection state of an antenna.

According to an aspect of the present invention, an amplifier module is disposed between an antenna for wireless communication and a main body portion of a wireless communication device, and is connected to the antenna via a first wiring member and to the main body portion via a second wiring member. The amplifier module includes an antenna-side terminal to which the first wiring member is connected, a main body-side terminal to which the second wiring member is connected, an amplifier disposed between the antenna-side terminal and the main body-side terminal, an impedance detector that detects impedance of the antenna-side terminal, a determiner that determines a connection state of the antenna to the antenna-side terminal based on the impedance detected by the impedance detector; and a controller that causes the amplifier to output a first state signal representing the connection state to the main body-side terminal, when the determiner determines that the connection state is abnormal.

### BRIEF DESCRIPTION OF THE DRAWINGS

FIG. 1 is a diagram illustrating an example of arrangement of an amplifier module and a wireless communication system according to an embodiment;

FIG. 2A is a diagram illustrating an example of a circuit configuration of the wireless communication system according to the embodiment;

FIG. 2B is a diagram illustrating an example of an internal configuration of the amplifier module according to the embodiment;

FIG. 3 is a diagram illustrating examples of first, second, and third state signals;

FIG. 4 is a flowchart of an example of a process performed by an MCU of the amplifier module according to the embodiment; and

FIG. 5 is a diagram illustrating an example of a circuit configuration of a wireless communication system according to a modification of the embodiment.

### DESCRIPTION OF THE PREFERRED EMBODIMENTS

The following is a description of an embodiment to which an amplifier module and a wireless communication system according to the present invention are applied.

### Embodiment

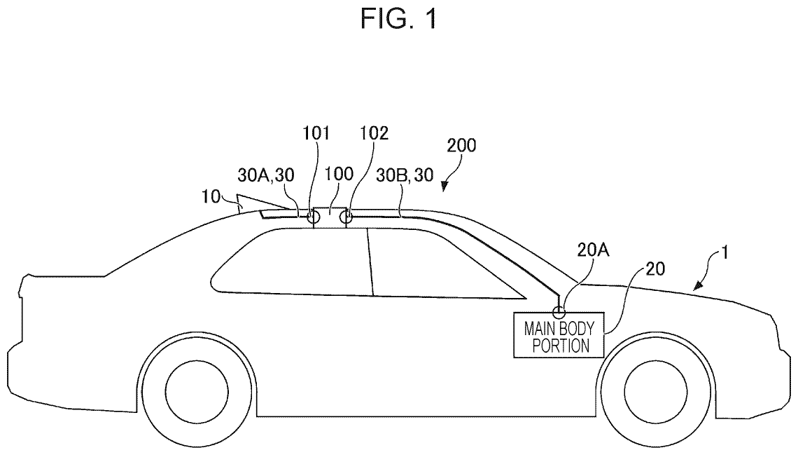

FIG. 1 is a diagram illustrating an example of arrangement of an amplifier module 100 and a wireless communication system 200 according to an embodiment. A vehicle 1 includes a wireless communication antenna 10, a main body portion 20 of a wireless communication device, a communication cable 30 (30A and 30B), and an amplifier module 100. The wireless communication system 200 includes the antenna 10, the main body portion 20, the cable 30 (30A and 30B), and the amplifier module 100. The cable 30A is an example of a first wiring member and the cable 30B is an example of a second wiring member.

The vehicle 1 is typically a passenger car, but may be any form of vehicle. Furthermore, although the antenna 10 is for C-V2X communication (a general term of inter-vehicle communication and road-to-vehicle communication using a cellular) disposed at a rear end of a roof of the vehicle 1, the antenna 10 is not limited to this type. The cable 30 includes the cable 30A connecting the antenna 10 and the amplifier module 100 to each other and the cable 30B connecting the amplifier module 100 and the main body portion 20.

The main body portion 20 is a main functional portion of the wireless communication device. The main body portion 20 includes a terminal 20A connected to the cable 30B. The main body portion 20, combined with the antenna 10, the cable 30, and the amplifier module 100, constitutes the wireless communication device. The main body portion 20 is a navigation electronic control unit (ECU) having a wireless communication function, for example, and is disposed near a dashboard of the vehicle 1. The amplifier module 100 is connected to the antenna 10 via the cable 30A and to the main body portion 20 via the cable 30B. The amplifier module 100 is disposed between the antenna 10 and the main body portion 20 in the electrical connection relationship via the cables 30A and 30B. As the cable 30, coaxial cables and the like are used in consideration of effects of electromagnetic noise, etc., but the cable 30 is not limited to this type.

The cable 30A is routed behind a roof of the vehicle 1 as an example, and the cable 30B is routed inside an A-pillar of the vehicle 1 and behind the roof as an example. The cables 30A and 30B have FAKRA plugs as an example, and the antenna 10, the main body portion 20, and the amplifier module 100 may be easily inserted and removed because they have FAKRA jacks.

The amplifier module 100 is disposed behind the roof of the vehicle 1, more specifically between a roof panel of a body of the vehicle 1 and a ceiling panel on an interior side of the vehicle, as an example. The amplifier module 100 has an antenna-side terminal 101 and a main body-side terminal 102. The cable 30A is connected to the antenna-side terminal 101, and the cable 30B is connected to the main body-side terminal 102.

The amplifier module 100 is disposed in a narrow space of a limited size, such as a portion between the roof panel of the vehicle 1 and the ceiling panel on the interior side of the vehicle. Therefore, the amplifier module 100 is connected to the antenna 10 by the single cable 30A, and the amplifier module 100 is also connected to the main body portion 20 by the single cable 30B. This is because the space for the cables 30A and 30B is limited.

In the wireless communication system 200, electric power is supplied from the main body portion 20 to the amplifier module 100 using the single cable 30B, and signals for communication are transmitted and received among the main body portion 20, the amplifier module 100, and the antenna 10 using the cables 30A and 30B. In addition, the wireless communication system 200 uses the cables 30A and 30B among the main body portion 20, the amplifier module 100, and the antenna 10 to transmit an abnormality of a connection state or the like of the antenna 10 from the amplifier module 100 to the main body portion 20.

The amplifier module 100 is at least disposed between (at a middle point of) the antenna 10 and the main body portion 20, or may be disposed in a position between the antenna 10 and the main body portion 20 where a length of the cable 30A and a length of the cable 30B are equal to each other. When the lengths of the cables 30A and 30B are equal to each other, the amplifier module 100 is disposed in a middle point of the length of the cable 30. Such an arrangement is preferable for improving a degree of freedom of installation of the amplifier module 100 in the vehicle interior space. Considering a loss of a transmission signal and a loss of a reception signal, it is more preferable to make the cable 30A shorter than the cable 30B.

Furthermore, it is not necessarily the case that the amplifier module 100 is disposed in the middle point of the length of the cable 30, and the amplifier module 100 may be disposed on an inner side of the A pillar in a position where the cable 30B is shorter than the cable 30A.

Conversely, the cable 30A may be shorter than the cable 30B. In this case, in a path between the antenna 10 and the main body portion 20 where the cable 30 is disposed, the amplifier module 100 may be disposed in a position nearer the antenna 10 relative to a point in which a distance from the antenna 10 and a distance from the main body portion 20 are equal to each other, and a signal level may be compensated for in the position near the antenna 10. In general, a reception signal has a signal level lower than that of a transmission signal and is easily affected by electromagnetic wave noise or the like. Therefore, the amplifier module 100 is disposed near the antenna 10 so that influence of the electromagnetic wave noise on the reception signal is easily suppressed. Therefore, such an arrangement is particularly suitable when priority is given to suppressing the influence of the electromagnetic wave noise and other factors on the reception signal.

The amplifier module 100 determines a connection state of the antenna 10 to the antenna-side terminal 101 based on impedance of the antenna-side terminal 101 while being connected to the main body portion 20 via the cable 30B.

There are three connection states of the antenna 10 to the antenna-side terminal 101, as examples. The first is a state in which the antenna 10 is normally connected to the antenna-side terminal 101 via the cable 30A (normal connection state) without any abnormalities, such as a short circuit in the cable 30A.

The second is a state in which the antenna 10 and the cable 30A are not connected to the antenna-side terminal 101 and the antenna-side terminal 101 is open (open state). The open state also occurs when the cable 30A is connected to the antenna-side terminal 101 but the antenna 10 is disconnected from the cable 30A.

The third is a state in which a short circuit occurs between the antenna-side terminal 101 and a ground potential point due to a connection of an antenna of a different type than the antenna 10 that is to be connected to the cable 30A, or for other reasons (short circuit state). The short circuit state may be entered due to dust, moisture from condensation, or the like.

The open state and the short circuit state occur when the connection of the antenna 10 to the antenna-side terminal 101 is abnormal.

The amplifier module 100 determines a connection state of the antenna 10 to the antenna-side terminal 101 while being connected to the main body portion 20 via the cable 30B, and as a result, when the connection state is abnormal, the amplifier module 100 causes a signal amplifier 110 to output a first state signal representing the connection state to the main body-side terminal 102. The first state signal output to the main body-side terminal 102 is transmitted to the main body portion 20 via the cable 30B. The first state signal indicates whether a connection state of the antenna 10 to the antenna-side terminal 101 is the open state or the short circuit state. The main body portion 20 may detect the occurrence of the open state or the short circuit state based on the first state signal. Details of the first state signal will be described hereinafter.

The amplifier module 100 has a temperature sensor that detects a temperature of the amplifier module 100, and based on a temperature detected by the temperature sensor, determines whether a temperature abnormality in the amplifier module 100 has occurred. When determining that a temperature abnormality has occurred, the amplifier module 100 causes the signal amplifier 110 to output a second state signal representing the temperature abnormality to the main body-side terminal 102. The second state signal output to the main body-side terminal 102 is transmitted to the main body portion 20 via the cable 30B. The second state signal indicates that the temperature of the amplifier module 100 is abnormal. Since the second state signal is different from the first state signal, the main body portion 20 may detect the occurrence of a temperature abnormality in the amplifier module 100 based on the second state signal. Details of the second state signal will be described hereinafter.

The amplifier module 100 determines whether an abnormality in an amount of current on a transmission side of the signal amplifier 110 has occurred based on an amount of current input from the main body-side terminal 102. When detecting an abnormal current amount, the amplifier module 100 causes the signal amplifier 110 to output a third state signal indicating the abnormal current amount on the transmission side of the signal amplifier 110 to the main body-side terminal 102. The third state signal output to the main body-side terminal 102 is transmitted to the main body portion 20 via the cable 30B. The third state signal indicates that an amount of current supplied from the cable 30B to the transmission side of the signal amplifier 110 of the amplifier module 100 via the main body-side terminal 102 is abnormal. Since the third state signal is different from the first and second state signals, the main body portion 20 may detect, based on the third state signal, that the abnormality has occurred in the amount of current on the transmission side of the signal amplifier 110. Details of the third state signal will be described hereinafter.

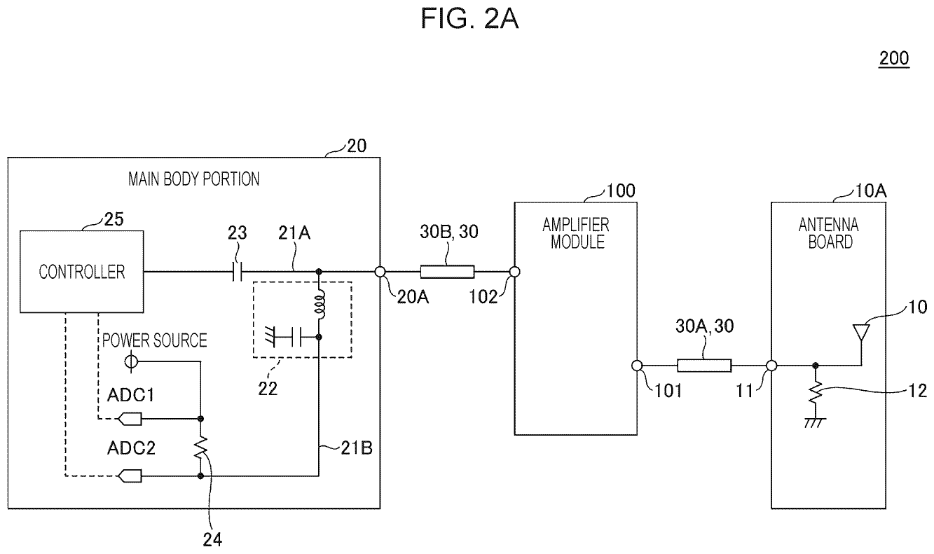

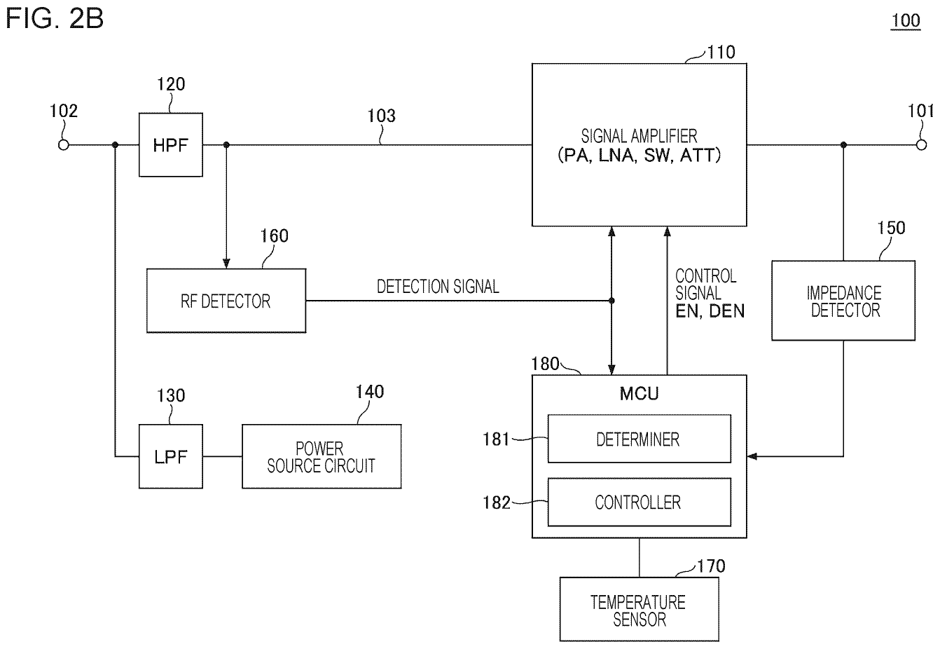

FIG. 2A is a diagram illustrating an example of a circuit configuration of the wireless communication system 200. The wireless communication system 200 includes the antenna 10, an antenna board 10A, the main body portion 20, the cable 30 (30A and 30B), and the amplifier module 100.

### Antenna 10

The antenna 10 is mounted on the antenna board 10A. The antenna board 10A is a wiring substrate of a standard of FR4 (Flame Retardant type 4) or the like. The antenna 10 is connected to a terminal 11 of the antenna board 10A. The antenna board 10A has the terminal 11 and a resistor 12. The terminal 11 is connected to the cable 30A, and further connected to the antenna-side terminal 101 of the amplifier module 100 via the cable 30A.

The resistor 12 branches off from a point between the antenna 10 and the terminal 11 and is connected to the ground potential point. The resistor 12 is used by the amplifier module 100 to detect impedance when a connection state of the antenna 10 to the antenna-side terminal 101 is determined.

### Main Body Portion 20

The main body portion 20 has a terminal 20A, lines 21A and 21B, a filter circuit 22, a capacitor 23, a resistor 24, an ADC1 (Analog to Digital Converter 1), an ADC2, and a controller 25.

The terminal 20A is connected to the cable 30B, and further connected to the main body-side terminal 102 of the amplifier module 100 via the cable 30B. The terminal 20A is connected to the line 21A inside the main body portion 20. The terminal 20A outputs electric power and an RF (Radio Frequency) signal from the main body portion 20 to the amplifier module 100, and the RF signal is input from the amplifier module 100 via the terminal 20A. The RF signal is, as an example, used for C-V2X communication.

The line 21A is used to connect the terminal 20A to the controller 25. The line 21B which branches off from the line 21A, is connected to the line 21A on the terminal 20A side, and the capacitor 23 for DC disconnection is inserted in series between a point where the line 21B branches and the controller 25.

The line 21B is used to connect the point branched from the line 21A to a power source. A coil of the filter circuit 22 and the resistor 24 are inserted in series in the line 21B. The power source is provided for the vehicle 1 and is connected to a battery as an example. The power source supplies DC power.

The filter circuit 22 is a low pass filter (LPF) and has the coil and a capacitor. The coil is inserted in series in the line 21B, and the capacitor is connected to the ground potential point on the power source side relative to the coil. The filter circuit 22 intercepts noise included in the DC power supplied from the power source and outputs the DC power to line 21A.

The resistor 24 is connected in series to the line 21B on the power source side so that the amplifier module 100 may monitor the current in the main body portion 20.

The ADC1 and the ADC2 are connected to respective ends of the resistor 24. The ADC1 digitally converts a voltage on the power source side of the resistor 24 and outputs data representing a value of the voltage to the controller 25. The ADC2 digitally converts a voltage on the filter circuit 22 side of the resistor 24 and outputs data representing a value of the voltage to the controller 25. The controller 25 uses the voltage value input from the ADC1 and the voltage value input from the ADC2 to obtain an amount of current flowing in the line 21B.

The controller 25 controls the main body portion 20, and as an example, performs transmission and reception processing for the wireless communication system 200 to transmit and receive RF signals in C-V2X communication. The controller 25 monitors an amount of current supplied from the main body portion 20 to the amplifier module 100 based on a difference in the voltage values input from the ADC1 and the ADC2. The difference in current values is, as an example, obtained by subtracting the voltage value of the ADC2 from the voltage value of the ADC1. This is because current flows in a direction from the power source to the filter circuit 22.

### Amplifier Module 100

The amplifier module 100 is described with reference to FIG. 2B in addition to FIG. 2A. FIG. 2B is a diagram illustrating an example of an internal configuration of the amplifier module 100.

The amplifier module 100 has the antenna-side terminal 101, the main body-side terminal 102, a line 103, the signal amplifier 110, a High Pass Filter (HPF) 120, a Low Pass Filter (LPF) 130, a power source circuit 140, an impedance detector 150, an RF detector 160, a temperature sensor 170, and a Micro Controller Unit (MCU) 180. The signal amplifier 110 is an example of an amplification section.

### Antenna-Side Terminal 101 and Main Body-Side Terminal 102

The antenna-side terminal 101 is connected to the cable 30A (see FIG. 2A) and is further connected to the antenna 10 via the cable 30A. The main body-side terminal 102 is connected to the cable 30B (see FIG. 2A) and is further connected to the main body portion 20 via the cable 30B.

### Line 103

The line 103 is used to connect the antenna-side terminal 101 to the main body-side terminal 102 inside the amplifier module 100.

### Signal Amplifier 110

The signal amplifier 110 is inserted in series in the line 103. The signal amplifier 110 includes a Power Amplifier (PA), a Low Noise Amplifier (LNA), a Switch (SW), and an Attenuator (ATT), as an example.

The PA amplifies an RF signal for transmission to be output from the antenna-side terminal 101 to the antenna 10. The LNA is an amplifier that amplifies the RF signal received by the antenna 10 and input from the antenna-side terminal 101. The SW performs switching between a transmission path including the PA and a reception path including the LNA. The ATT is an attenuator that adjusts a signal level of a transmission signal to keep a level suitable and compliant with the communication standard.

The signal amplifier 110 is a front-end module including an integrated circuit (IC) as an example. The signal amplifier 110 is set to a normal state for a normal operation by an enabling signal (EN) input from the MCU 180, and is set to a sleep state by a disabling signal (DEN) input from the MCU 180. In the sleep state, the amplification operation of the signal amplifier 110 is disabled. The signal amplifier 110 is set to its normal state when not in the sleep state. In the normal state, the signal amplifier 110 is woken up from the sleep state and the amplification operation of the signal amplifier 110 is enabled.

In the sleep state, an output from the signal amplifier 110 to the main body-side terminal 102 is at a predetermined low level (hereinafter referred to as an “L level”). In the sleep state, the amplification operation of the signal amplifier 110 is disabled and the amplification operation of the LNA that amplifies a signal transmitted from the antenna-side terminal 101 to the main body-side terminal 102 is disabled, so an output level from the signal amplifier 110 to the main body-side terminal 102 becomes an L level.

Furthermore, in the normal state, an output from the signal amplifier 110 to the main body-side terminal 102 is at a predetermined high level (hereinafter referred to as an “H level”). The H level is higher than the L level. In the normal state, the amplification operation of the signal amplifier 110 is enabled and the amplification operation of the LNA that amplifies a signal transmitted from the antenna-side terminal 101 to the main body-side terminal 102 is enabled, so the output level from the signal amplifier 110 to the main body-side terminal 102 becomes the H level which is higher than the L level. In a case of transmission, a signal for transmission from the main body portion 20 is input from the main body portion 20 to the main body-side terminal 102, and therefore, the signal is brought to the H level.

The signal amplifier 110 has a function of detecting an amount of current input to the PA of the signal amplifier 110 from the main body-side terminal 102, and outputs a digital signal representing the detected amount of current to the MCU 180.

### HPF 120 and LPF 130

The HPF 120 is inserted into the line 103 inside the amplifier module 100, between the main body-side terminal 102 and the signal amplifier 110. The LPF 130 is inserted in a line branching from a point between the main body-side terminal 102 and the HPF 120 toward the power source circuit 140 inside the amplifier module 100.

The HPF 120 and the LPF 130 are disposed to separate an RF signal input from the main body-side terminal 102 from the DC power. The RF signal input from the main body-side terminal 102 passes through the HPF 120 and is transmitted to the signal amplifier 110, but does not pass through the LPF 130, and therefore, is not supplied to the power source circuit 140. The DC power input from the main body-side terminal 102 is supplied to the power source circuit 140 through the LPF 130, but is not transmitted to the signal amplifier 110 because the DC power does not pass through the HPF 120.

### Power Source Circuit 140

The power source circuit 140 is connected to the line branching from the line 103 at the point between the main body-side terminal 102 and the HPF 120, and is connected to the main body-side terminal 102 via the LPF 130. The power source circuit 140 supplies DC power to the signal amplifier 110, the impedance detector 150, the RF detector 160, the temperature sensor 170, and the MCU 180 through power source lines not illustrated.

### Impedance Detector 150

The impedance detector 150 is inserted in a line branching off from the line 103 between the antenna-side terminal 101 and the signal amplifier 110, and has an input terminal connected to the antenna-side terminal 101 and an output terminal connected to the MCU 180.

The impedance detector 150 detects impedance of the antenna-side terminal 101 and outputs a digital signal representing the impedance to the MCU 180. The impedance of the antenna-side terminal 101 detected by the impedance detector 150 differs depending on whether a connection state of the antenna 10 to the antenna-side terminal 101 is the normal state, the open state, or the short circuit state.

### RF Detector 160

The RF detector 160 is connected while branching off from the line 103 at a position on an output side of the HPF 120. The RF detector 160 has an input terminal connected to the output terminal of the HPF 120 and an output terminal connected to the signal amplifier 110 and the MCU 180. The RF detector 160 detects an RF signal output from the HPF 120. When detecting an RF signal, the RF detector 160 outputs a detection signal indicating the detection to the signal amplifier 110 and the MCU 180.

As a result, the signal amplifier 110 performs switching of the SW to the transmission path in accordance with the detection signal, and the MCU 180 controls the PA for transmission (setting a PA amplification factor, etc.) according to the detection signal. The signal amplifier 110 switches the SW to the reception path when a detection signal is not input, and the MCU 180 performs control for reception (e.g., a setting an amplification factor of the LNA) when a detection signal is not input.

### Temperature Sensor 170

The temperature sensor 170 is disposed in a housing of the amplifier module 100, as an example, and detects a temperature of the amplifier module 100. The temperature sensor 170 outputs a digital signal representing the detected temperature to the MCU 180. The temperature sensor 170 may be disposed in the MCU 180.

### MCU 180

The MCU 180 is implemented by a computer that includes a Central Processing Unit (CPU), a Random Access Memory (RAM), a Read Only Memory (ROM), an input/output interface, and an internal bus.

The MCU 180 has a determiner 181 and a controller 182. The determiner 181 and the controller 182 are illustrated as functional blocks of functions of programs to be executed by the MCU 180. The MCU 180 has a functional processor and a memory in addition to the determiner 181 and the controller 182, but these are omitted in FIG. 2B. Note that the memory of the MCU 180 is realized by a RAM, a ROM, etc.

### Determiner 181

The determiner 181 determines a connection state (normal state, open state, or short circuit state) of the antenna 10 to the antenna-side terminal 101 based on the impedance detected by the impedance detector 150.

Furthermore, the determiner 181 determines whether a temperature abnormality has occurred in the amplifier module 100 based on the temperature detected by the temperature sensor 170. The determiner 181 determines whether a temperature abnormality has occurred in the amplifier module 100 when the temperature represented by the digital signal input from the temperature sensor 170 is equal to or higher than a predetermined threshold value.

Furthermore, the determiner 181 determines whether an abnormality is detected in an amount of current input to the PA of the signal amplifier 110 from the main body-side terminal 102 based on the digital signal input from the signal amplifier 110. An abnormality in the amount of current input to the PA of the signal amplifier 110 is an abnormality in the amount of current on the transmission side of the signal amplifier 110.

### Controller 182

When the determiner 181 determines that a connection state is abnormal, the controller 182 causes the signal amplifier 110 to output a first state signal representing the connection state from the main body-side terminal 102 to the cable 30B.

The controller 182 outputs control signals that control the PA of the signal amplifier 110, the amplification factor of the LNA, and the like. Furthermore, the controller 182 performs switching between an enabling signal (EN) and a disabling signal (DEN) to be output to the signal amplifier 110 in a time-divisional manner to enable and disable the amplification operation of the signal amplifier 110, thereby causing the signal amplifier 110 to output a first state signal.

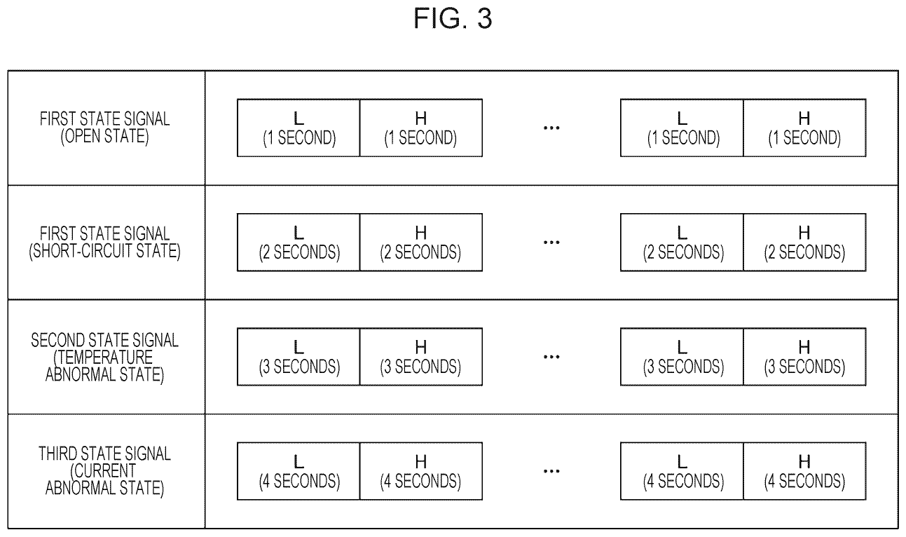

More specifically, the controller 182 changes a first period during which the enabling signal is output to the signal amplifier 110 and a second period during which the disabling signal is output to the signal amplifier 110 in accordance with a type of abnormality in the connection state, so as to cause the signal amplifier 110 to output a first state signal representing the type of abnormality. This operation will be described in detail below with reference to FIG. 3.

Examples of the type of abnormality include an open connection state of the antenna 10 to the antenna-side terminal 101 and a short circuit connection state of the antenna 10 to the antenna-side terminal 101.

Furthermore, when the determiner 181 determines that a temperature abnormality has occurred, the controller 182 causes the signal amplifier 110 to output a second state signal representing the temperature abnormality to the main body-side terminal 102.

Moreover, when the determiner 181 determines that an abnormality in an amount of current input to the PA of the signal amplifier 110 from the main body-side terminal 102 has occurred, the controller 182 causes the signal amplifier 110 to output a third state signal indicating the abnormality in the amount of current in the signal amplifier 110 to the main body-side terminal 102.

The first state signal, the second state signal, and the third state signal are output from the signal amplifier 110 to the main body-side terminal 102 under control of the controller 182, and signal levels thereof are switched between an H level and an L level in a time-divisional manner by the signal amplifier 110 under control of the controller 182 when the controller 182 selectively outputs the enabling signal and the disabling signal in a time-divisional manner to the signal amplifier 110.

The signal levels of the first state signal, the second state signal, and the third state signal all have different patterns of switching between the H and L levels in a time-divisional manner. Furthermore, the pattern in which the signal level of the first state signal is switched between the H and L levels in a time-divisional manner differs between the short circuit state and the open state. This operation will be described in detail below with reference to FIG. 3.

### First State Signal, Second State Signal, and Third State Signal

FIG. 3 is a diagram illustrating examples of first, second, and third state signals. The four state signals used by the amplifier module 100 are, as examples, the first state signal for the open state, the first state signal for the short circuit state, the second state signal for the temperature abnormal state, and the third state signal for the abnormal current state.

In FIG. 3, examples of the order of the L and H levels and durations of the individual levels in the first state signal for the open state, the first state signal for the short circuit state, the second state signal for the temperature abnormal state, and the third state signal for the abnormal current state are illustrated. The L level in the individual state signals is an example of a first signal level, and the H level in the individual state signals is an example of a second signal level. Furthermore, L-level periods in the individual state signals are examples of the first period, and H-level periods in the individual state signals are examples of the second period.

### First State Signal for Open State

The first state signal in the open state has, as an example, L and H levels which are alternately switched for one second each. The first state signal for the open state is output from the signal amplifier 110 to the main body-side terminal 102 by the controller 182 which alternately outputs the disabling signal and the enabling signal for one second each. Thus, the first state signal for the open state has first and second periods in accordance with the open state. Therefore, the occurrence of the open state may be transmitted to the controller 25 of the main body portion 20.

### First State Signal for Short Circuit State

The first state signal for the short circuit state has, as an example, L and H levels which are alternately changed for two seconds each. The first state signal for the short circuit state is output from the signal amplifier 110 to the main body-side terminal 102 by the controller 182 which alternately outputs the disabling signal and the enabling signal for two seconds each. Thus, the first state signal for the short circuit state has first and second periods in accordance with the short circuit state. Therefore, the occurrence of the short circuit state may be transmitted to the controller 25 of the main body portion 20.

### Second State Signal

The second state signal has, as an example, L and H levels which are alternately switched for three second each. The second state signal is output from the signal amplifier 110 to the main body-side terminal 102 by the controller 182 which alternately outputs the disabling signal and the enabling signal for three seconds each. Thus, the second state signal has first and second periods in accordance with the temperature abnormality. Therefore, the occurrence of the temperature abnormal state may be transmitted to the controller 25 of the main body portion 20.

### Third State Signal

The third state signal has, as an example, L and H levels which are alternately switched for four seconds each. The third state signal is output from the signal amplifier 110 to the main body-side terminal 102 by the controller 182 which alternately outputs the disabling signal and the enabling signal for four seconds each. Thus, the third state signal has first and second periods in accordance with the current amount abnormality on the transmission side of the signal amplifier 110. Therefore, the occurrence of the current abnormal state may be transmitted to the controller 25 of the main body portion 20.

The first state signal for the open state, the first state signal for the short circuit state, the second state signal for the temperature abnormal state, and the third state signal for the abnormal current state last 10 to 20 seconds, as an example.

Thus, by using the first state signal for the open state, the first state signal for the short circuit state, the second state signal for the temperature abnormal state, and the third state signal for the abnormal current state with different durations of L and H levels, the amplifier module 100 may notify the main body portion 20 of the type of abnormality through the cable 30B.

Note that, although the four state signals, that is, the first state signal for the open state, the first state signal for the short circuit state, the second state signal for the temperature abnormal state, and the third state signal for the abnormal current state, are illustrated in FIG. 3 as examples, state signals for notifying the main body portion 20 of other abnormalities may be added or may be used instead of the above four state signals. By changing the combination of the first and second periods, notifications of various abnormalities, etc. may be transmitted to the main body portion 20.

Furthermore, although a signal pattern in which the L and H level periods are equal in the individual state signals is illustrated in FIG. 3, the L and H level periods in at least one of the state signals may not be equal. For example, the first state signal for the open state may alternately perform switching between the L level for one second and the H level for two seconds, as an example.

Although FIG. 3 shows a signal pattern in which the L-level and H-level periods are set to the same period when repeating the L-level and H-level periods for each state signal, the periods may be different when repeating the L-level and H-level periods for at least one of the state signals. For example, in the first state signal for the open state, as an example, the signal may alternate between L and H levels for one second, followed by 2 seconds of alternating L and H levels.

Furthermore, when the amplifier module 100 does not include the temperature sensor 170, the controller 182 does not alternately output the disabling and enabling signals in a pattern for causing the signal amplifier 110 to generate the second state signal.

Moreover, when the amplifier module 100 does not detect a current abnormality, the controller 182 does not alternately output the disabling and enabling signals in a pattern for causing the signal amplifier 110 to generate the third state signal.

### Flowchart

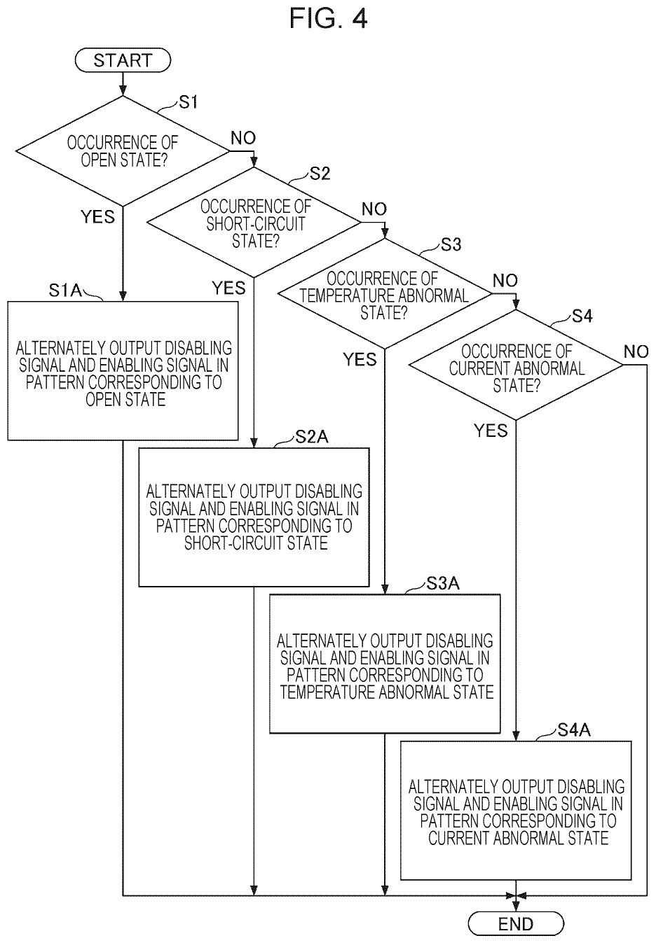

FIG. 4 is a flowchart of an example of a process executed by the MCU 180. When starting the process, the MCU 180 performs the following process.

The determiner 181 determines whether the open state has occurred based on the digital signal input from the impedance detector 150 (step S1).

When the determiner 181 determines that the open state has occurred (S1: YES), the controller 182 alternately switches the disabling and enabling signals in the pattern corresponding to the open state and outputs the disabling and enabling signals to the signal amplifier 110 (step S1A). When terminating the process in step S1A, the MCU 180 terminates the series of processes (end).

When determining that the open state has not occurred in step S1 (S1: NO), the determiner 181 determines whether the short circuit state has occurred based on the digital signal input from the impedance detector 150 (step S2).

When the determiner 181 determines that the short circuit state has occurred (S2: YES), the controller 182 alternately switches the disabling and enabling signals in the pattern corresponding to the short circuit state and outputs the disabling and enabling signals to the signal amplifier 110 (step S2A). When terminating the process in step S2A, the MCU 180 terminates the series of processes (end).

Furthermore, when determining that the short circuit state has not occurred in step S2 (S2: NO), the determiner 181 determines whether the temperature abnormal state has occurred based on the digital signal input from the temperature sensor 170 (step S3).

When the determiner 181 determines that the temperature abnormal state has occurred (S3: YES), the controller 182 alternately switches the disabling and enabling signals in the pattern corresponding to the temperature abnormal state and outputs the disabling and enabling signals to the signal amplifier 110 (step S3A). When terminating the process in step S3A, the MCU 180 terminates the series of processes (end).

Furthermore, when determining that the temperature abnormal state has not occurred in step S3 (S3: NO), the determiner 181 determines whether the current abnormal state has occurred based on the digital signal input from the signal amplifier 110 (step S4).

When the determiner 181 determines that the current abnormal state has occurred (S4: YES), the controller 182 alternately switches the disabling and enabling signals in the pattern corresponding to the current abnormal state and outputs the disabling and enabling signals to the signal amplifier 110 (step S4A). When terminating the process in step S4A, the MCU 180 terminates the series of processes (end).

Furthermore, when determining that the current abnormal state has not occurred in step S4 (S4: NO), the determiner 181 terminates the series of processes (end).

### Wireless Communication System 200M in Modification of Embodiment

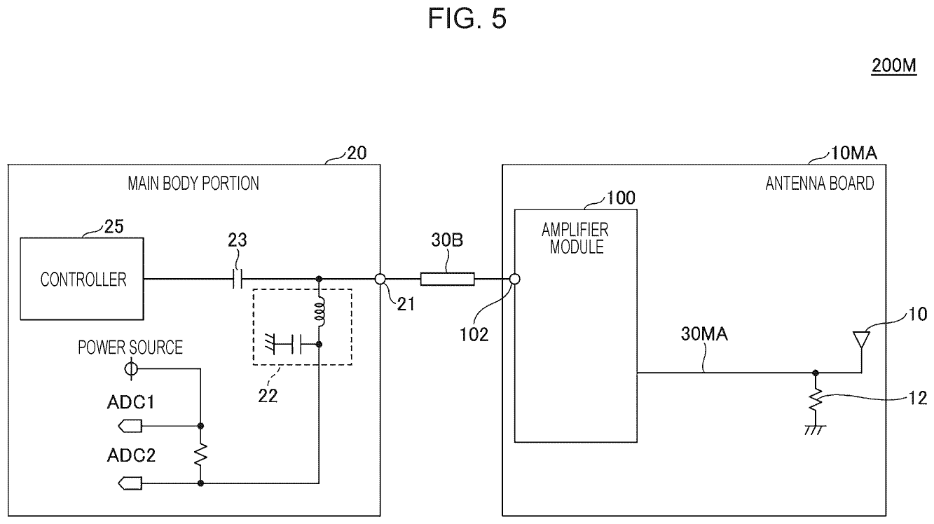

FIG. 5 is a diagram illustrating an example of a circuit configuration of a wireless communication system 200M according to a modification of the embodiment.

The wireless communication system 200M includes an antenna 10, an antenna board 10MA, a main body portion 20, a cable 30B, and an amplifier module 100. In the wireless communication system 200M, the antenna 10 and the amplifier module 100 are mounted on the antenna board 10MA. The antenna board 10MA has a resistor 12 and is a wiring substrate similar to the antenna board 10A illustrated in FIG. 2A.

The wireless communication system 200M is configured such that the amplifier module 100 of the wireless communication system 200 illustrated in FIG. 2A is implemented on the antenna board 10MA and the amplifier module 100 and the antenna 10 are connected to each other by a line 30MA. The line 30MA is an example of a first wiring member and a cable 30B is an example of a second wiring member.

Thus, the wireless communication system 200M having the configuration in which the amplifier module 100 is mounted on the antenna board 10MA and the amplifier module 100 and the antenna 10 are connected by the line 30MA may operate in the same manner as the wireless communication system 200 illustrated in FIG. 2A and has the same effect.

### Effect

The amplifier module 100 is disposed between the antenna 10 for wireless communication and the main body portion 20 of a wireless communication device, and is connected to the antenna 10 via the cable 30A (first wiring member) and to the main body portion 20 via the cable 30B (second wiring member). The amplifier module 100 includes the antenna-side terminal 101 to which the cable 30A is connected, the main body-side terminal 102 to which the cable 30B is connected, the signal amplifier 110 (amplifier section) provided between the antenna-side terminal 101 and the main body-side terminal 102, and the impedance detector 150 that detects impedance of the antenna-side terminal 101, a determiner 181 that determines a connection state of the antenna 10 to the antenna-side terminal 101 based on the impedance detected by the impedance detector 150, and the controller 182 that causes the signal amplifier 110 to output the first state signal representing the connection state to the main body-side terminal 102 when the determiner 181 determines that the connection state is abnormal. Thus, a notification of the connection state of the antenna 10 may be transmitted to the main body portion 20 when the signal amplifier 110 outputs the first state signal representing the connection state of the antenna 10 to the main body-side terminal 102. Since the signal amplifier 110 outputs the first state signal to the main body-side terminal 102, circuits are not required to be added to generate the first state signal.

Accordingly, the amplifier module 100 that may notify the main body portion 20 of a connection state of the antenna 10 may be provided with a simple configuration. Under the restriction that the amplifier module 100 and the antenna 10 are connected by the single cable 30A and the amplifier module 100 and the main body portion 20 are also connected by the single cable 30B, a notification of the connection state of the antenna 10 may be transmitted to the main body portion 20 with a simple configuration that does not require additional circuitry.

Furthermore, the signal amplifier 110 may be configured to enable and disable an amplification operation by the disabling and enabling signals, and the controller 182 may enable and disable the amplification operation of the signal amplifier 110 by switching the disabling and enabling signals to be output to the signal amplifier 110 in a time-divisional manner so as to cause the signal amplifier 110 to output the first state signal. Therefore, the first state signal corresponding to the output signals of the main body-side terminal 102 in the enabling and disabling states of the amplification operation of the signal amplifier 110 may be output, and the amplifier module 100 with a simple configuration which is capable of notifying the main body portion 20 of the connection state of the antenna 10 with the first state signal that may be easily output may be provided.

More specifically, the controller 182 changes a first period during which the disabling signal is output to the signal amplifier 110 and a second period during which the enabling signal is output to the signal amplifier 110 in accordance with a type of abnormality in the connection state, so as to cause the signal amplifier 110 to output the first state signal representing the type of abnormality. By changing the first and second periods in accordance with the type of abnormality of the connection state, the first state signal indicating the type of abnormality may be easily output.

The first and second periods may be equal to each other. When the first and second periods are equal to each other, the type of abnormality may be simply represented by the first state signal.

Furthermore, the controller 182 alternately switches the disabling and enabling signals to be output to the signal amplifier 110 each time the first and second periods alternate, and the first state signal may alternate between a first signal level corresponding to the disabling signal over the first period and a second signal level corresponding to the enabling signal over the second period. The first state signal, which alternates between the first signal level over the first period and the second signal level over the second period, may indicate the type of abnormality.

The type of abnormality may include an open connection state of the antenna 10 relative to the antenna-side terminal 101 and a short circuit connection state of the antenna 10 relative to the antenna-side terminal 101. The open state of the antenna 10 and the short circuit state of the antenna 10 may be transmitted to the main body portion 20 by the first state signals indicating the open state of the antenna 10 and the short circuit state of the antenna 10.

The temperature sensor 170 detecting a temperature of the amplifier module 100 may be further included, and the determiner 181 may further determine whether a temperature abnormality of the amplifier module 100 has occurred based on a temperature detected by the temperature sensor 170, and the controller 182 may cause, when the determiner 181 determines that a temperature abnormality has occurred, the signal amplifier 110 to output the second state signal representing the temperature abnormality to the main body-side terminal 102. Thus, since the signal amplifier 110 outputs the second state signal representing the temperature abnormality state of the amplifier module 100 to the main body-side terminal 102, a notification of the temperature abnormality state of the amplifier module 100 may be transmitted to the main body portion 20. Since the signal amplifier 110 outputs the second state signal to the main body-side terminal 102, circuits are not required to be added to generate the second state signal. Accordingly, in addition to the connection state of the antenna 10, the amplifier module 100 may notify the main body portion 20 of a temperature abnormality of the amplifier module 100, and the amplifier module 100 may be provided with a simple configuration.

The temperature sensor 170 detecting a temperature of the amplifier module 100 is further included, and the determiner 181 further determines whether a temperature abnormality of the amplifier module 100 is occurring based on the temperature detected by the temperature sensor 170, and the controller 182 performs, when the determiner 181 determines that the temperature abnormality is occurring, switching between disabling and enabling signals in a time-divisional manner to enable and disable the amplification operation of the signal amplifier 110, thereby causing the signal amplifier 110 to output a second state signal representing a temperature abnormality to the main body-side terminal 102. The second state signal has a first and second periods corresponding to the temperature abnormality, and the first and second periods of the second state signal may be different from the first and second periods of the first state signal. Therefore, the second state signal corresponding to the output signals of the main body-side terminal 102 in the enabling and disabling states of the amplification operation of the signal amplifier 110 may be output, and the amplifier module 100 with a simple configuration which is capable of notifying the main body portion 20 of the temperature abnormality of the amplifier module 100 with the second state signal that may be easily output may be provided. Furthermore, by changing the first and second periods in accordance with the temperature abnormality of the amplifier module 100 and the connection state abnormality of the antenna 10, the second state signal representing the temperature abnormality of the amplifier module 100 and the first state signal representing the connection state abnormality of the antenna 10 may be easily output.

Furthermore, the controller 182 alternately switches the disabling and enabling signals to be output to the signal amplifier 110 each time the first and second periods alternate, and the second state signal may alternate between a first signal level corresponding to the disabling signal over the first period and a second signal level corresponding to the enabling signal over the second period. The second state signal, which alternates between the first signal level over the first period and the second signal level over the second period, may indicate the temperature abnormality of the amplifier module 100.

The determiner 181 may further determine whether an abnormality in the amount of current is occurring based on the amount of current input to the signal amplifier 110 from the main body-side terminal 102, and the controller 182 may cause, when the determiner 181 determines that an abnormality in the amount of current is occurring, the signal amplifier 110 to output the third state signal indicating the abnormality in the amount of current to the main body-side terminal 102. Thus, a notification of the abnormal state of the current amount may be transmitted to the main body portion 20 when the signal amplifier 110 outputs the third state signal representing the abnormal state of the current amount to the main body-side terminal 102. Since the signal amplifier 110 outputs the third state signal to the main body-side terminal 102, circuits are not required to be added to generate the third state signal. Accordingly, in addition to the connection state of the antenna 10, the amplifier module 100 may notify the main body portion 20 of a current amount abnormality of the signal amplifier 110, and the amplifier module 100 may be provided with a simple configuration.

The determiner 181 further determines whether a current amount abnormality is occurring based on the current amount input to the signal amplifier 110 from the main body-side terminal 102, and the controller 182 performs, when the determiner 181 determines that the current amount abnormality is occurring, switching between disabling and enabling signals in a time-divisional manner to enable and disable the amplification operation of the signal amplifier 110, thereby causing the signal amplifier 110 to output the third state signal representing the current amount abnormality to the main body-side terminal 102. The third state signal has a first and second periods corresponding to the current amount abnormality, and the first and second periods of the third state signal may be different from the first and second periods of the first state signal. Therefore, the third state signal corresponding to the output signals of the main body-side terminal 102 in the enabling and disabling states of the amplification operation of the signal amplifier 110 may be output, and the amplifier module 100 with a simple configuration which is capable of notifying the main body portion 20 of the current amount abnormality with the third state signal that may be easily output may be provided. Furthermore, by changing the first and second periods in accordance with the current amount abnormality of the signal amplifier 110 and the connection state abnormality of the antenna 10, the third state signal representing the current amount abnormality of the signal amplifier 110 and the first state signal representing the connection state abnormality of the antenna 10 may be easily output.

The controller 182 alternately switches the disabling and enabling signals to be output to the signal amplifier 110 each time the first and second periods alternate, and the third state signal may alternate between a first signal level corresponding to the disabling signal over the first period and a second signal level corresponding to the enabling signal over the second period. The third state signal, which alternates between the first signal level over the first period and the second signal level over the second period, may indicate the current amount abnormality of the signal amplifier 110.

The wireless communication system 200 includes the antenna 10 for wireless communication, the main body portion 20 of the wireless communication device, the cable 30A connected to the antenna 10, the cable 30B connected to the main body portion 20, and an amplifier module 100 that is disposed between the antenna 10 and the main body portion 20 and connected to the antenna 10 via the cable 30A and to the main body portion 20 via the cable 30B. The amplifier module 100 includes the antenna-side terminal 101 to which the cable 30A is connected, the main body-side terminal 102 to which the cable 30B is connected, the signal amplifier 110 disposed between the antenna-side terminal 101 and the main body-side terminal 102, the impedance detector 150 that detects impedance of the antenna-side terminal 101, the determiner 181 that determines a connection state of the antenna 10 relative to the antenna-side terminal 101 based on the impedance detected by the impedance detector 150, and the controller 182 that causes, when the determiner 181 determines that the connection state is abnormal, the signal amplifier 110 to output the first state signal representing the connection state to the main body-side terminal 102. Thus, a notification of the connection state of the antenna 10 may be transmitted to the main body portion 20 when the signal amplifier 110 outputs the first state signal representing the connection state of the antenna 10 to the main body-side terminal 102. Since the signal amplifier 110 outputs the first state signal to the main body-side terminal 102, circuits are not required to be added to generate the first state signal.

Accordingly, the wireless communication system 200 that may notify the main body portion 20 of a connection state of the antenna 10 may be provided with a simple configuration.

The amplifier module and wireless communication system of the exemplary embodiment of the present invention have been described above. The invention is not limited to the specifically disclosed embodiment, but various modifications and changes may be made without departing from the scope of the claims.

With respect to the above embodiments, the following appendices are further disclosed.

### Appendix 1

An amplifier module disposed between an antenna for wireless communication and a main body portion of a wireless communication device, and is connected to the antenna via a first wiring member and to the main body portion via a second wiring member, the amplifier module comprising:
an antenna-side terminal to which the first wiring member is connected;
a main body-side terminal to which the second wiring member is connected;
an amplifier disposed between the antenna-side terminal and the main body-side terminal;
an impedance detector that detects impedance of the antenna-side terminal;
a determiner that determines a connection state of the antenna to the antenna-side terminal based on the impedance detected by the impedance detector; and
a controller that causes the amplifier to output a first state signal representing the connection state to the main body-side terminal, when the determiner determines that the connection state is abnormal.

### Appendix 2

The amplifier module according to Appendix 1, wherein
the amplifier performs switching between enabling and disabling of an amplification operation by means of disabling and enabling signals, and
the controller causes the amplifier to output the first state signal by time-divisionally switching the disabling and enabling signals to be output to the amplifier to perform switching between enabling and disabling of the amplification operation of the amplifier.

### Appendix 3

The amplifier module according to Appendix 2, wherein the controller performs switching between a first period during which the disabling signal is output to the amplifier and a second period during which the enabling signal is output to the amplifier in accordance with the type of abnormality in the connection state, thereby causing the amplifier to output the first state signal representing the type of abnormality.

### Appendix 4

The amplifier module according to Appendix 3, wherein the first period is equal to the second period.

### Appendix 5

The amplifier module according to Appendix 3, wherein
the controller performs alternate switching between the disabling and enabling signals to be output to the amplifier every time one of the first and second periods elapses which alternately elapse, and
the first state signal is alternately brought into a first signal level corresponding to the disabling signal over the first period and a second signal level corresponding to the enabling signal over the second period.

### Appendix 6

The amplifier module according to Appendix 3, wherein the type of abnormality includes an open connection state of the antenna to the antenna-side terminal and a short circuit connection state of the antenna to the antenna-side terminal.

### Appendix 7

The amplifier module according to any one of Appendices 1 to 6, further comprising:
a temperature sensor that detects a temperature of the amplifier module, wherein
the determiner further determines whether a temperature abnormality is occurring in the amplifier module based on the temperature detected by the temperature sensor, and
the controller causes the amplifier to output a second state signal representing the temperature abnormality to the main body-side terminal when the determiner determines that the temperature abnormality is occurring.

### Appendix 8

The amplifier module according to any one of Appendices 3 to 6, further comprising:
a temperature sensor that detects a temperature of the amplifier module, wherein
the determiner further determines whether a temperature abnormality is occurring in the amplifier module based on the temperature detected by the temperature sensor,
when the determiner determines that the temperature abnormality is occurring, the controller performs switching between the disabling and enabling signals in a time-divisional manner to enable and disable the amplification operation of the amplifier, thereby causing the amplifier to output a second state signal representing the temperature abnormality to the main body-side terminal,
the second state signal has a first period and a second period according to the temperature abnormality, and
the first and second periods of the second state signal are different from the first and second periods of the first state signal.

### Appendix 9

The amplifier module according to Appendix 8, wherein
the controller performs alternate switching between the disabling and enabling signals to be output to the amplifier every time one of the first and second periods elapses which alternately elapse, and
the second state signal is alternately brought into a first signal level corresponding to the disabling signal over the first period and a second signal level corresponding to the enabling signal over the second period.

### Appendix 10

The amplifier module according to any one of Appendices 1 to 9, wherein
the determiner further determines whether an abnormality is occurring in an amount of current to be input from the main body-side terminal to the amplifier based on the current amount, and
the controller causes the amplifier to output a third state signal representing the abnormal current amount to the main body-side terminal when the determiner determines that the abnormality is detected in the current amount.

### Appendix 11

The amplifier module according to any one of Appendices 3 to 9, wherein
the determiner further determines whether an abnormality is occurring in an amount of current to be input from the main body-side terminal to the amplifier based on the current amount,
when the determiner determines that the current amount abnormality is occurring, the controller performs switching between the disabling and enabling signals in a time-divisional manner to enable and disable the amplification operation of the amplifier, thereby causing the amplifier to output a third state signal representing the current amount abnormality to the main body-side terminal,
the third state signal has the first period and the second period according to the current amount abnormality, and
the first and second periods of the third state signal are different from the first and second periods of the first state signal.

### Appendix 12

The amplifier module according to Appendix 11, wherein
the controller performs alternate switching between the disabling and enabling signals to be output to the amplifier every time one of the first and second periods elapses which alternately elapse, and
the third state signal is alternately brought into a first signal level corresponding to the disabling signal over the first period and a second signal level corresponding to the enabling signal over the second period.

### Appendix 13

A wireless communication system, comprising:
an antenna for wireless communication;
a main body portion of a wireless communication device;
a first wiring member connected to the antenna;
a second wiring member connected to the main body portion; and
an amplifier module which disposed between the antenna and the main body portion and which is connected to the antenna via a first wiring member and to the main body portion via a second wiring member, wherein
the amplifier module includes
an antenna-side terminal to which the first wiring member is connected,
a main body-side terminal to which the second wiring member is connected,
an amplifier disposed between the antenna-side terminal and the main body-side terminal;
an impedance detector that detects impedance of the antenna-side terminal,
a determiner that determines a connection state of the antenna to the antenna-side terminal based on the impedance detected by the impedance detector, and
a controller that causes the amplifier to output a first state signal representing the connection state to the main body-side terminal, when the determiner determines that the connection state is abnormal.

What is claimed is:

1. An amplifier module disposed between an antenna for wireless communication and a main body portion of a wireless communication device, and is connected to the antenna via a first wiring member and to the main body portion via a second wiring member, the amplifier module comprising:
an antenna-side terminal to which the first wiring member is connected;
a main body-side terminal to which the second wiring member is connected;
an amplifier disposed between the antenna-side terminal and the main body-side terminal;
an impedance detector that detects impedance of the antenna-side terminal;
a determiner that determines a connection state of the antenna to the antenna-side terminal based on the impedance detected by the impedance detector; and
a controller that causes the amplifier to output a first state signal representing the connection state to the main body-side terminal, when the determiner determines that the connection state is abnormal.

2. The amplifier module according to claim 1, wherein
the amplifier performs switching between enabling and disabling of an amplification operation by means of disabling and enabling signals, and
the controller causes the amplifier to output the first state signal by time-divisionally switching the disabling and enabling signals to be output to the amplifier to perform switching between enabling and disabling of the amplification operation of the amplifier.

3. The amplifier module according to claim 2, wherein the controller performs switching between a first period during which the disabling signal is output to the amplifier and a second period during which the enabling signal is output to the amplifier in accordance with the type of abnormality in the connection state, thereby causing the amplifier to output the first state signal representing the type of abnormality.

4. The amplifier module according to claim 3, wherein the first period is equal to the second period.

5. The amplifier module according to claim 3, wherein
the controller performs alternate switching between the disabling and enabling signals to be output to the amplifier every time one of the first and second periods elapses which alternately elapse, and
the first state signal is alternately brought into a first signal level corresponding to the disabling signal over the first period and a second signal level corresponding to the enabling signal over the second period.

6. The amplifier module according to claim 3, wherein the type of abnormality includes an open connection state of the antenna to the antenna-side terminal and a short circuit connection state of the antenna to the antenna-side terminal.

7. The amplifier module according to claim 1, further comprising:
a temperature sensor that detects a temperature of the amplifier module, wherein
the determiner further determines whether a temperature abnormality is occurring in the amplifier module based on the temperature detected by the temperature sensor, and
the controller causes the amplifier to output a second state signal representing the temperature abnormality to the main body-side terminal when the determiner determines that the temperature abnormality is occurring.

8. An amplifier module according to claim 3, further comprising:
a temperature sensor that detects a temperature of the amplifier module, wherein
the determiner further determines whether a temperature abnormality is occurring in the amplifier module based on the temperature detected by the temperature sensor,
when the determiner determines that the temperature abnormality is occurring, the controller performs switching between the disabling and enabling signals in a time-divisional manner to enable and disable the amplification operation of the amplifier, thereby causing the amplifier to output a second state signal representing the temperature abnormality to the main body-side terminal,
the second state signal has a first period and a second period according to the temperature abnormality, and
the first and second periods of the second state signal are different from the first and second periods of the first state signal.

9. The amplifier module according to claim 8, wherein
the controller performs alternate switching between the disabling and enabling signals to be output to the amplifier every time one of the first and second periods elapses which alternately elapse, and
the second state signal is alternately brought into a first signal level corresponding to the disabling signal over the first period and a second signal level corresponding to the enabling signal over the second period.

10. The amplifier module according to claim 1, wherein
the determiner further determines whether an abnormality is occurring in an amount of current to be input from the main body-side terminal to the amplifier based on the current amount, and
the controller causes the amplifier to output a third state signal representing the abnormal current amount to the main body-side terminal when the determiner determines that the abnormality is detected in the current amount.

11. The amplifier module according to claim 3, wherein
the determiner further determines whether an abnormality is occurring in an amount of current to be input from the main body-side terminal to the amplifier based on the current amount,
when the determiner determines that the current amount abnormality is occurring, the controller performs switching between the disabling and enabling signals in a time-divisional manner to enable and disable the amplification operation of the amplifier, thereby causing the amplifier to output a third state signal representing the current amount abnormality to the main body-side terminal,
the third state signal has the first period and the second period according to the current amount abnormality, and
the first and second periods of the third state signal are different from the first and second periods of the first state signal.

12. The amplifier module according to claim 11, wherein
the controller performs alternate switching between the disabling and enabling signals to be output to the amplifier every time one of the first and second periods elapses which alternately elapse, and
the third state signal is alternately brought into a first signal level corresponding to the disabling signal over the first period and a second signal level corresponding to the enabling signal over the second period.

13. A wireless communication system, comprising:
an antenna for wireless communication;
a main body portion of a wireless communication device;
a first wiring member connected to the antenna;
a second wiring member connected to the main body portion; and
an amplifier module which disposed between the antenna and the main body portion and which is connected to the antenna via a first wiring member and to the main body portion via a second wiring member, wherein
the amplifier module includes
an antenna-side terminal to which the first wiring member is connected,
a main body-side terminal to which the second wiring member is connected,
an amplifier disposed between the antenna-side terminal and the main body-side terminal,
an impedance detector that detects impedance of the antenna-side terminal,
a determiner that determines a connection state of the antenna to the antenna-side terminal based on the impedance detected by the impedance detector, and
a controller that causes the amplifier to output a first state signal representing the connection state to the main body-side terminal, when the determiner determines that the connection state is abnormal.
